(19) United States
(12) Patent Application Publication
(10) Pub. No.: US 2021/0278250 A1
(43) Pub. Date: Sep. 9, 2021

(54) MODULARIZED TOUCH GLASS BOARD AND CAPACITIVE TOUCH SENSOR INCLUDING THE SAME

(71) Applicants: Chih-Chiang Pai, Taoyuan (TW); Meng-Kuei Lin, Taoyuan (TW); Chin-Fong Lin, Taoyuan (TW)

(72) Inventors: Chih-Chiang Pai, Taoyuan (TW); Meng-Kuei Lin, Taoyuan (TW); Chin-Fong Lin, Taoyuan (TW)

(73) Assignee: Young Fast Optoelectronics Co., Ltd., Taoyuan (TW)

(21) Appl. No.: 16/813,714

(22) Filed: Mar. 9, 2020

(51) Int. Cl. G01D 5/24

(52) U.S. Cl. CPC G01D 5/2405; G01R 27/2605

(57) ABSTRACT

A touch glass board includes a glass substrate. Conductive bars, which are arranged along a direction and have the same widths, are disposed on each of two opposite sides of the glass substrate. Every adjacent two of the conductive bars are separated by an insulation gap. The conductive bars on a side of the glass substrate are orthogonal to those on the other side. The conductive bars are divided into multiple electrode groups. Each electrode group includes two or more of the conductive bars. Selective more than two of the conductive bars are connected to form an active electrode unit. Pluralities of the active electrode units are electrically connected to a signal wire to form a touch sensing layer. The two touch sensing layers on two sides of the glass substrate jointly form a capacitive touch sensor.

### TECHNICAL FIELD

The invention relates to capacitive touch sensors, particularly to a modularized touch glass board and a capacitive touch sensor including the same.

### RELATED ART

A conventional capacitive touch sensor mounted on a display is usually made of an indium tin oxide (ITO) film. A touch sensor is formed by etching touch sensing electrodes and signal wires on the ITO film. Design and production of touch sensors must be adjusted to correspond to several factors such as product size, a capacitance range of the touch ICs, etc. For example, the acquired touch sensing signal value can be adjusted by changing the area of sensing electrode and the sensitivity of touch sensing can be adjusted by changing the electrode group pitch. As a result, with the various requirements of touch panels with different sizes, the pressure on the stockpile cost increases substantially. Also, the manufacturing process becomes more complicated and spends longer time.

### SUMMARY OF THE INVENTION

An object of the invention is to provide a modularized touch glass board and a capacitive touch sensor including the same. Each of two opposite sides of a glass substrate is provided with a conductive layer. The conductive layer has a modularized preset trace pattern. The modularized preset trace pattern includes parallel conductive bars and conductive bars with an identical pitch. Every adjacent two of the conductive bars are separated by an insulation gap. The conductive bars and the insulation gaps have respective uniform sizes. Accordingly, when the board is used to make a touch sensor, a manufacture can select a touch glass board with a corresponding size. A trace pattern is preset in an active area and all conductive material outside the active area is removed so that a desired touch trace pattern is formed. The conductive bars in the touch trace pattern are divided into multiple electrode groups. Each electrode group includes two or more conductive bars. An active electrode unit is formed by either one conductive bar or selective more than one of the conductive bars connected. The active electrode units of the electrode groups are electrically connected to signal wires to form a touch sensing layer. The two touch sensing layers on two sides of the glass substrate jointly form a capacitive touch sensor.

As a result, according to the invention, changing the number of combination of the conductive bars of the electrode group can change the pitch width between two electrode groups. This can be used to adjust accuracy of touch sensing position. Also, changing the number of connected conductive bars of the active electrode units can adjust the acquired touch sensing capacitance to meet the working capacitance range set by various manufacturers of touch ICs. Therefore, the invention can accomplish uniformization of touch glass boards so that the categories of material stockpiles can be simplified, the stockpile cost can be reduced, the flexibility and simplification of design of touch sensors can be enhanced, the manufacturing process can be simplified and the efficiency of production can be increased.

Further, according to the invention, the modularized touch glass board includes a glass substrate with a first conductive layer and a second conductive layer, which are separately disposed on two opposite sides of the glass substrate. The first conductive layer has a modularized first preset trace pattern. The first preset trace pattern includes first conductive bars which are arranged along a first direction and have the same widths. The first conductive bars are equally spaced out with a width of a first pitch. Every adjacent two of the first conductive bars are separated by a first insulation gap. The second conductive layer has a modularized second preset trace pattern. The second preset trace pattern includes second conductive bars which are arranged along a second direction and have the same widths. The second conductive bars are equally spaced out with a width of a second pitch. Every adjacent two of the second conductive bars are separated by a second insulation gap. The first direction is orthogonal to the second direction. The width of the first pitch is the same as the width of the second pitch. The width is below 2 mm. Each of the first insulation gap and the second insulation gap is between 500 and 20 μm.

In the invention, each of the first and second conductive layers is a transparent conductive film and is made of metal oxide or graphene, and the metal oxide is indium tin oxide, indium zinc oxide, zinc aluminum oxide, tin antimony oxide or polyethylene dioxythiophene.

In the invention, each of the first and second conductive bars is of a strip shape, a jagged strip shape or a strip shape formed by a series of geometric areas, but not limited to these.

In the invention, a low-resistance unit is further electrically attached on each of the first and second conductive bars for reducing surface resistance of the conductive bars, the low-resistance unit is made of gold, silver, copper, aluminum, molybdenum or an alloy thereof, the low-resistance unit is composed of one or more of pointy, linear and planar shapes, the low-resistance unit is a metal wire or a metal mesh, a width of the metal wire is below 10 μm, the low-resistance unit comprises one or more continuous straight linear metal wires or curved metal wires, and preferably, a shading rate of the metal mesh is under 1%.

According to the invention, the capacitive touch sensor includes: a substrate, being dielectric, and an active touch area being defined in a central portion thereof; a first touch sensing layer, disposed on a first side of the substrate, having a first touch trace pattern and a first signal wire, the first touch trace pattern being formed in the active touch area of the substrate, the first signal wire being disposed outside the active touch area, the first touch trace pattern having first conductive bars which are arranged along a first direction, the first conductive bars being equally spaced out with a width of a first pitch, every adjacent two of the first conductive bars being separated by a first insulation gap, the first conductive bars being divided into multiple first electrode groups, the first electrode groups being spaced out with a width of a first electrode group pitch, each first electrode group comprising at least two of the first conductive bars, a first active electrode unit being formed by either one of the first conductive bars or selective more than one of the first conductive bars connected, and the first active electrode unit being electrically connected to the first signal wire; and a second touch sensing layer, disposed on a second side of the substrate, having a second touch trace pattern and a second signal wire, the second touch trace pattern being formed in the active touch area of the substrate, the second signal wire being disposed outside the active touch area, the second touch trace pattern having second conductive bars which are arranged along a second direction, the second conductive bars being equally spaced out with a width of a second pitch, every adjacent two of the second conductive bars being separated by a second insulation gap, the second conductive bars being divided into multiple second electrode groups, the second electrode groups being spaced out with a width of a second electrode group pitch, each second electrode group comprising at least two of the second conductive bars, a second active electrode unit being formed by either one of the second conductive bars or selective more than one of the second conductive bars connected, and the second active electrode unit being electrically connected to the second signal wire. The first direction is orthogonal to the second direction. The width of the first electrode group pitch is the same as the width of the second electrode group pitch. The first touch sensing layer and the second touch sensing layer jointly form a capacitive touch sensor.

In the invention, the first pitch is the same as the second pitch in width, the width is below 2 mm, and each of the first insulation gap and the second insulation gap is between 500 and 20 μm.

In the invention, each of the first and second touch sensing layers is a transparent conductive film and is made of metal oxide or graphene, and the metal oxide is indium tin oxide, indium zinc oxide, zinc aluminum oxide, tin antimony oxide or polyethylene dioxythiophene, but not limited to these.

In the invention, each of the first and second conductive bars is of a strip shape, a jagged strip shape or a strip shape formed by a series of geometric areas, but not limited to these.

In the invention, one or more of the first conductive bars of the first electrode group which is or are not connected to the first active electrode unit is or are connected to the ground wire, and one or more of the second conductive bars of the second electrode group which is or are not connected to the second active electrode unit is or are connected to the ground wire. This can enhance anti-interference ability of the touch sensor.

In the invention, the first active electrode unit is a driving electrode, the second active electrode is a sensing electrode, and the first active electrode unit is greater than the second active electrode unit in area.

In the invention, a low-resistance unit is further electrically attached on each of the first and second conductive bars for reducing surface resistance of the conductive bars, the low-resistance unit is made of gold, silver, copper, aluminum, molybdenum or an alloy thereof, the low-resistance unit is composed of one or more of pointy, linear and planar shapes, the low-resistance unit is a metal wire or a metal mesh, a width of the metal wire is below 10 μm, the low-resistance unit comprises one or more continuous straight linear metal wires or curved metal wires, and preferably, a shading rate of the metal mesh is under 1%.

### BRIEF DESCRIPTION OF THE DRAWINGS

FIG. 1 is a side schematic view of laminated structure of the modularized touch glass board;

FIG. 2 is a plan view of the upper conductive layer of the modularized touch glass board;

FIG. 3 is a plan view of the lower conductive layer of the modularized touch glass board;

FIG. 4 is a plan view of laminated structure of the modularized touch glass board;

FIG. 5a is a plan schematic view of another conductive bar of the modularized touch glass board;

FIG. 5b is a plan schematic view of still another conductive bar of the modularized touch glass board;

FIG. 6 is a plan view of the conductive bar with a low-resistance unit of the modularized touch glass board;

FIG. 7 is a plan view of laminated structure of the capacitive touch sensor;

FIG. 8 is a plan view of the substrate of the capacitive touch sensor;

FIG. 9 is a plan view of the upper conductive layer of the capacitive touch sensor;

FIG. 10 is a plan view of the lower conductive layer of the capacitive touch sensor;

FIG. 11 is a plan view of laminated structure of another capacitive touch sensor;

FIG. 12 is a plan view of the upper conductive layer of another capacitive touch sensor; and

FIG. 13 is a plan view of the lower conductive layer of another capacitive touch sensor.

### DETAILED DESCRIPTION OF THE INVENTION

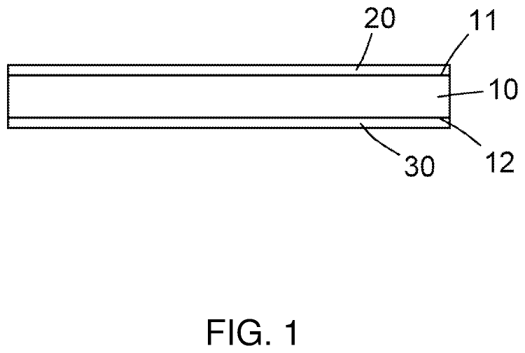

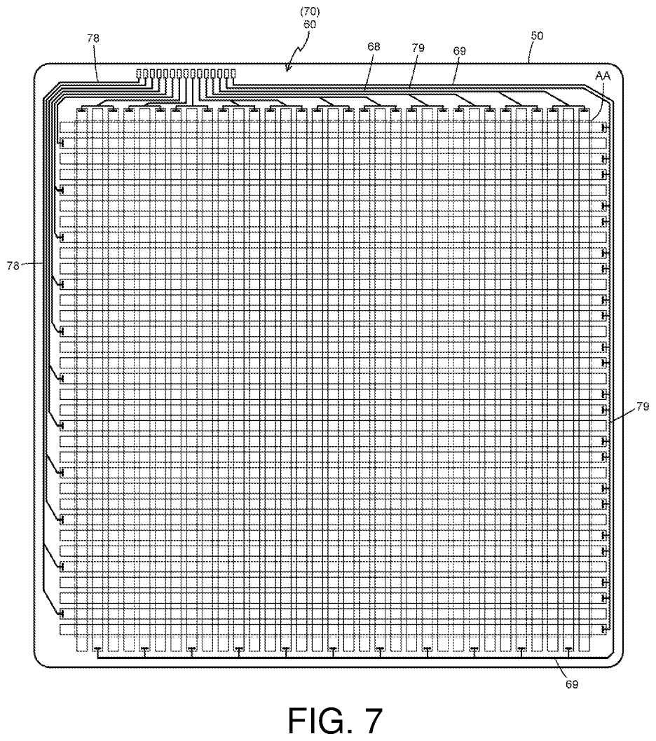

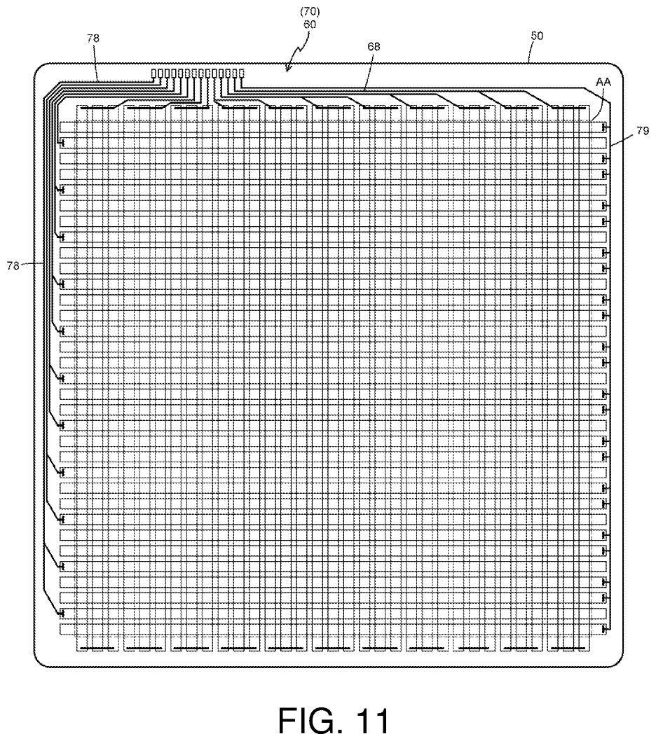

FIGS. 1-6 depict an embodiment of the modularized touch glass board of the invention. FIGS. 7-10 depict the first embodiment of the capacitive touch sensor of the invention. FIGS. 11-13 depict the second embodiment of the capacitive touch sensor of the invention. Preferred embodiments are depicted in the drawings. To make the invention more understandable, some elements in the drawings are not drawn in an accurate scale and sizes of some elements are enlarged with respect to other elements. For the sake of clearness, irrelative details are not drawn.

As shown in FIG. 1, the modularized touch glass board of the invention includes a glass substrate 10, an upper conductive layer 20 and a lower conductive layer 30.

The glass substrate 10 is a glass board with high transmittance and has an upper surface 11 and a lower surface 12, which are wide and flat.

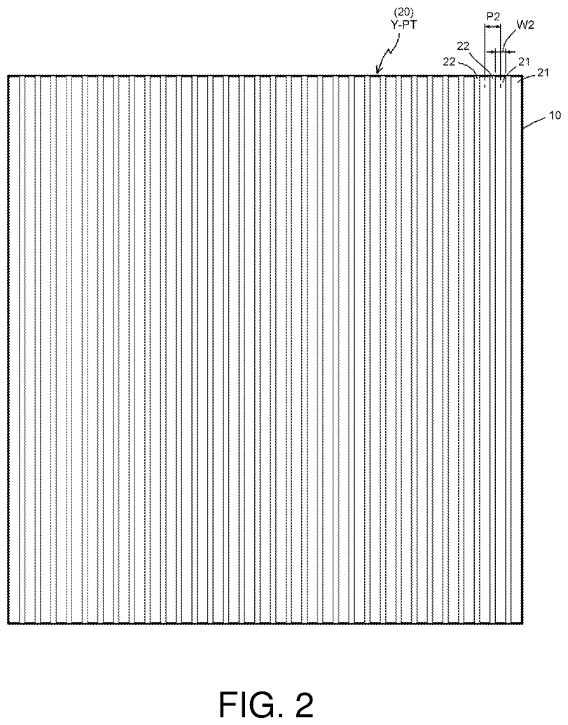

The upper conductive layer 20 is made of a conductive material with high transmittance, such as indium tin oxide (ITO). As shown in FIG. 2, the upper conductive layer 20 is disposed on the upper surface 11 of the glass substrate 10. The upper conductive layer 20 has modularized Y-axis preset trace pattern Y-PT. There are Y-axis conductive bars 21 parallelly along Y-axis in the Y-axis preset trace pattern Y-PT. Each Y-axis conductive bar 21 has an identical width W2 and is set with an identical pitch P2 from each other. Every adjacent two of the Y-axis conductive bars 21 are separated by an insulation gap 22.

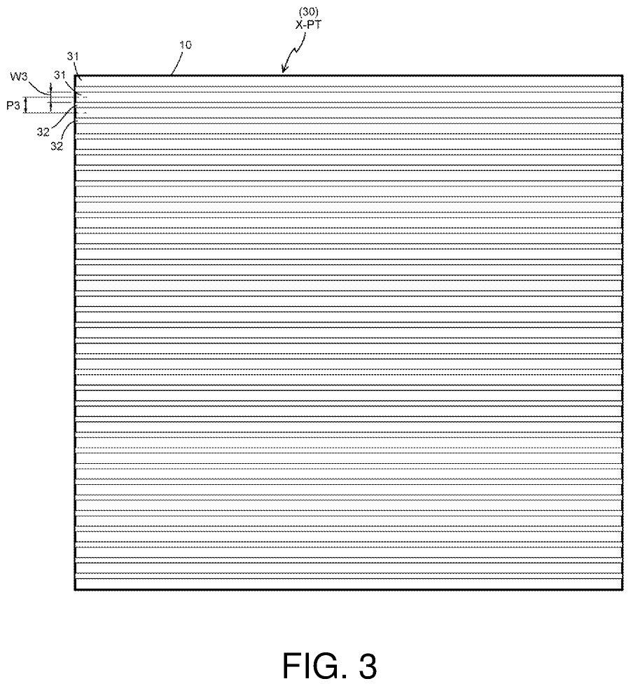

The lower conductive layer 30 is made of a conductive material with high transmittance, such as indium tin oxide (ITO). As shown in FIG. 3, the lower conductive layer 30 is disposed on the lower surface 12 of the glass substrate 10. The lower conductive layer 30 has modularized X-axis preset trace pattern X-PT. There are X-axis conductive bars 31 parallelly along X-axis in the X-axis preset trace pattern X-PT. Each X-axis conductive bar 31 has an identical width W3 and is set with an identical pitch P3 from each other. Every two of the X-axis conductive bars 31 are separated by an insulation gap 32.

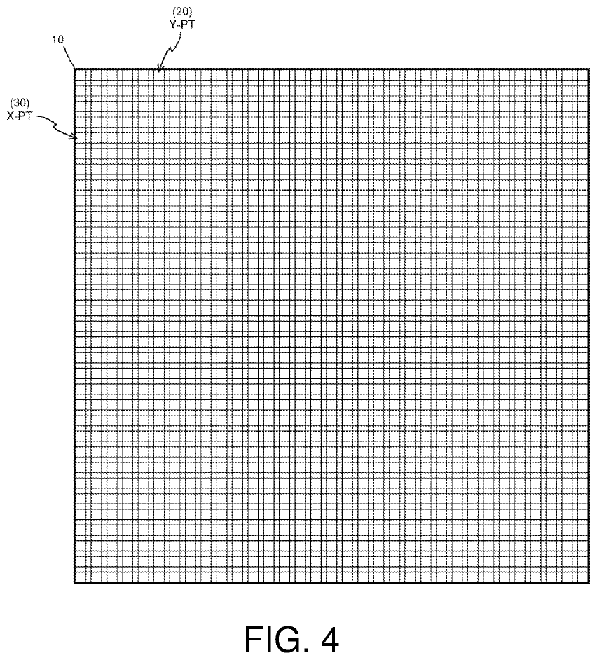

FIG. 4 shows a touch glass board jointly constituted by the glass substrate 10, the upper conductive layer 20 and the lower conductive layer 30. The pitch P2 between the Y-axis conductive bars 21 is the same as the pitch P3 between the X-axis conductive bars 31. Preferably, each of the pitches P2, P3 is set to be about 2mm wide. In actual applications, these pitches can be adjusted depending on the specification of touch sensors, for example, small pitch can increase accuracy of touch sensing position. Each of the insulation gaps 22, 32 is set to be between 500 μm and 20 μm for insulating and separating two adjacent conductive bars. The insulation gaps 22, 32 may be adjusted according to active area of the conductive bars, for example, the insulation gaps 22, 32 become larger when the active area of the conductive bars is smaller.

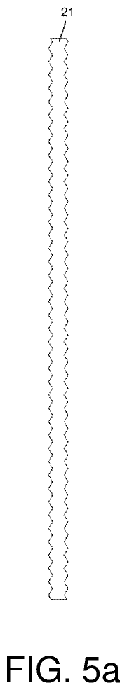

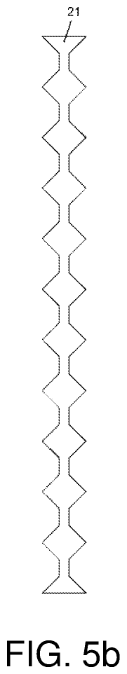

In addition, as shown in FIGS. 2 and 3, each of the Y-axis conductive bars 21 and the X-axis conductive bars 31 is of a strip shape, but in other available solutions, the conductive bar may also be of a jagged strip shape as shown in FIG. 5a or a strip shape formed by a series of geometric areas (such as rhombus) as shown in FIG. 5b. Particularly, because such a transparent touch sensor is usually mounted on an LCD, the passing light may generate Moire to affect the image quality if edges of conductive bars are straight. Thus, a jagged strip shape of the conductive bar can prevent or reduce the problem of optical interference.

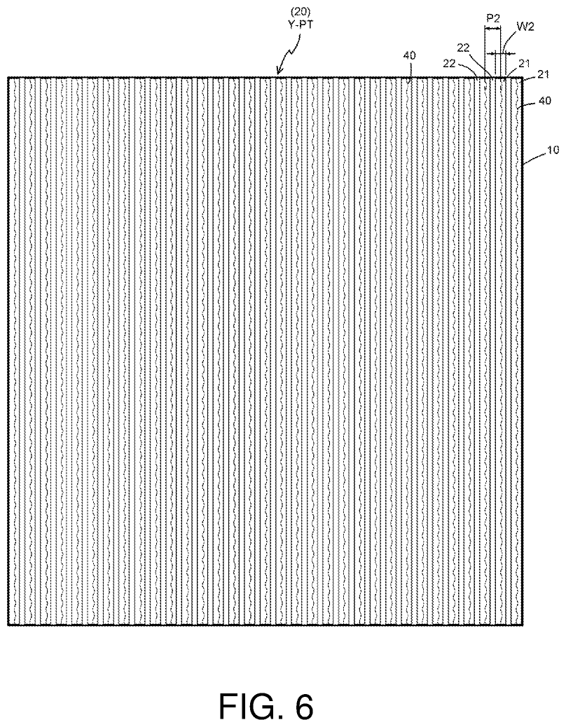

Please refer to FIG. 6, which shows an embodiment of a conductive bar electrically connected with a low-resistance unit. In this embodiment, the low-resistance unit 40 is a nanometer-sized curved metal wire attached on the Y-axis conductive bar 21 for reducing the surface resistance of the ITO conductive bar. The metal wire is preferably below 10 μm to prevent the transmittance of the conductive bar from being impeded. The metal wire may be made of gold, silver, copper, aluminum, molybdenum or an alloy thereof. The low-resistance unit 40 may also be a straight-line metal wire, a dotted-line metal wire or a metal mesh with a shading rate under 1%.

FIGS. 7-10 depict the first embodiment of the capacitive touch sensor using the abovementioned modularized touch glass board. The capacitive touch sensor includes a glass substrate 50, an upper touch sensing layer 60 and a lower touch sensing layer 70.

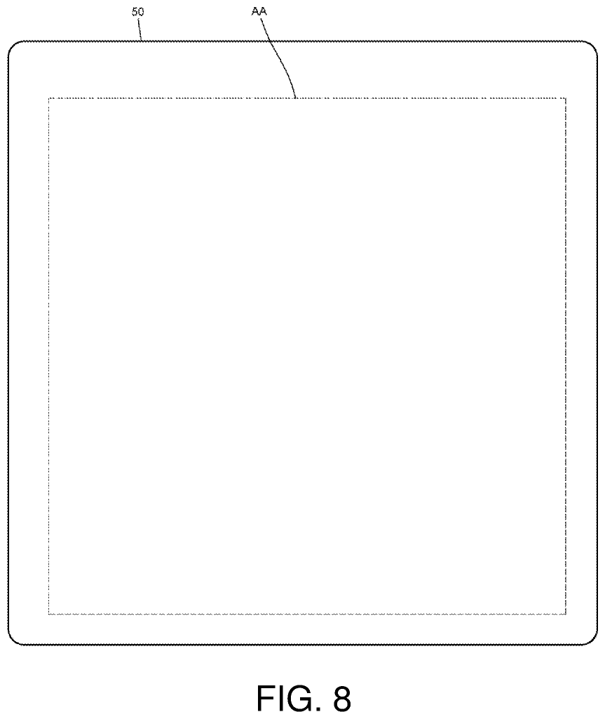

As shown in FIG. 8, the glass substrate 50 is a glass board with high transmittance. An active touch area AA is defined in a central portion of the glass substrate 50.

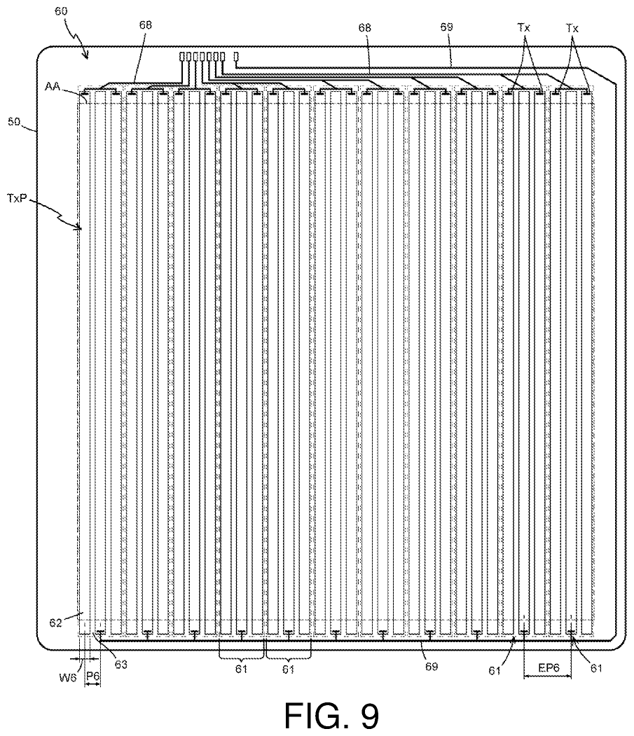

As shown in FIG. 9, the upper touch sensing layer 60 is disposed on the upper surface of the glass substrate 50. The upper touch sensing layer 60 includes a driving electrode trace pattern TxP (Tx pattern), driving signal wires 68 and a ground wire 69. The driving electrode trace pattern TxP is formed in the active touch area AA of the glass substrate 50. The driving signal wires 68 and the ground wire 69 are disposed outside the active touch area AA. The driving electrode trace pattern TxP includes driving electrode groups 61 which are arranged parallelly along the Y-axis direction. An identical electrode group pitch EP6 is disposed between every adjacent two driving electrode groups 61. The driving electrode group 61 includes three Y-axis conductive bars 62 along the Y-axis direction. Each Y-axis conductive bar 62 has an identical width W6 and is set with an identical pitch P6 from each other. Every adjacent two of the Y-axis conductive bars 62 are separated by an insulation gap 63. Two of the Y-axis conductive bars 62 are electrically connected to form an active driving electrode unit Tx. The active driving electrode units Tx are connected to the driving signal wires 68 and the only one of the Y-axis conductive bars 62 which is not connected to the active driving electrode units Tx is connected to the ground wire 69.

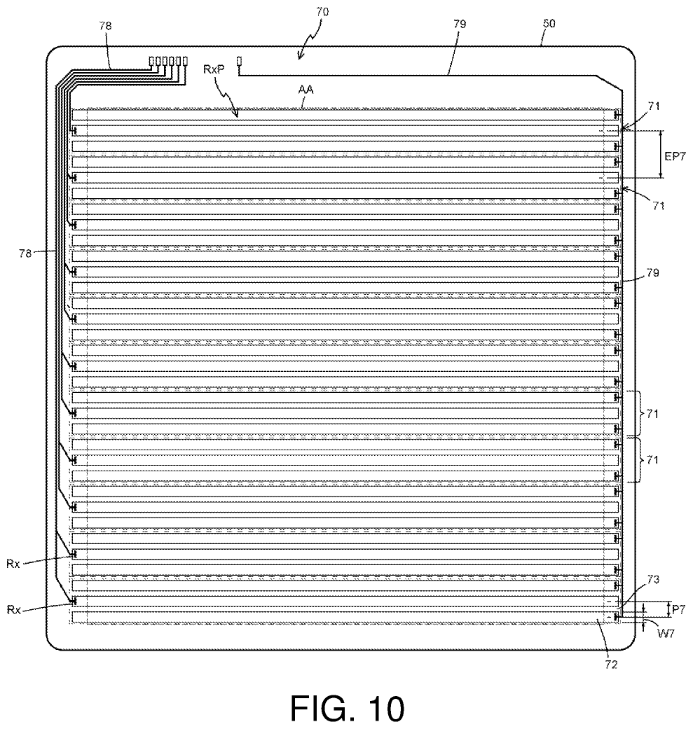

As shown FIG. 10, the lower touch sensing layer 70 is disposed on the lower surface of the glass substrate 50. The lower touch sensing layer 70 includes a sensing electrode trace pattern RxP (Rx pattern), sensing signal wires 78 and a ground wire 79. The sensing electrode trace pattern RxP is formed in the active touch area AA of the glass substrate 50. The sensing signal wires 78 and the ground wire 79 are disposed outside the active touch area AA. The sensing electrode trace pattern RxP includes sensing electrode groups 71 which are arranged parallelly along the X-axis direction. An identical electrode group pitch EP7 is disposed between every adjacent two sensing electrode groups 71. The sensing electrode group 71 includes three X-axis conductive bars 72 along the X-axis direction. Each X-axis conductive bar 72 has an identical width W7 and is set with an identical pitch P7 from each other. Every adjacent two of the X-axis conductive bars 72 are separated by an insulation gap 73. One of the X-axis conductive bars 72 is set to be an active sensing electrode unit Rx. The active sensing electrode units Rx are connected to the sensing signal wire 78 and the two of the X-axis conductive bars 72 which are not connected to the active sensing electrode units Rx are connected to the ground wire 79. The pitch P6 between the Y-axis conductive bars 62 is the same as the pitch P7 between the X-axis conductive bars 72. Each of the pitches P6, P7 is set to be 2mm. The Y-axis insulation gap 63 is set to be 20 μm and the X-axis insulation gap 73 is set to be 300 μm, so that the width W6 of the Y-axis conductive bar 62 is greater than the width W7 of the X-axis conductive bar 72. In other words, the Y-axis conductive bar 62 is greater than the X-axis conductive bar in area. FIG. 7 shows the capacitive touch sensor jointly composed of the glass substrate 50, the upper touch sensing layer 60 and the lower sensing layer 70. In this embodiment, the driving electrodes are disposed on the upper touch sensing layer 60, and the sensing electrodes are disposed on the lower touch sensing layer 70. The electrode group pitch EP6 between the driving electrode groups 61 is the same as the electrode group pitch EP7 between the sensing electrode groups 71. Each of the electrode group pitches EP6, EP7 is set to be 6mm. The active driving electrode unit Tx is greater than the active sensing electrode unit Rx in area.

Further, in the above embodiment, the driving electrode group 61 includes three Y-axis conductive bars 62, and the sensing electrode group 71 includes three X-axis conductive bars 72. However, when it is applied to a sensor with a large size, the driving electrode group 61 and the sensing electrode group 71 may include more Y-axis conductive bars 62 and X-axis conductive bars 72, respectively, for example, six, ten or more for increasing the size of the electrode group pitch EP6, EP7 to fit a sensor with a large size. In addition, changing the number of the Y-axis and X-axis conductive bars 62, 72 connected to the active driving electrode unit Tx and the active sensing electrode unit Rx can adjust the acquired touch sensing capacitance to meet a range of the working capacitance of the touch ICs from different manufacturers. Accordingly, the invention uses changing the compositive number of the conductive bars in the driving electrode group 61 and the sensing electrode 71 and/or changing the number of the conductive bars connected to the active driving electrode unit Tx and the active sensing electrode unit Rx to adjust a size of the touch sensor and a range of the working capacitance.

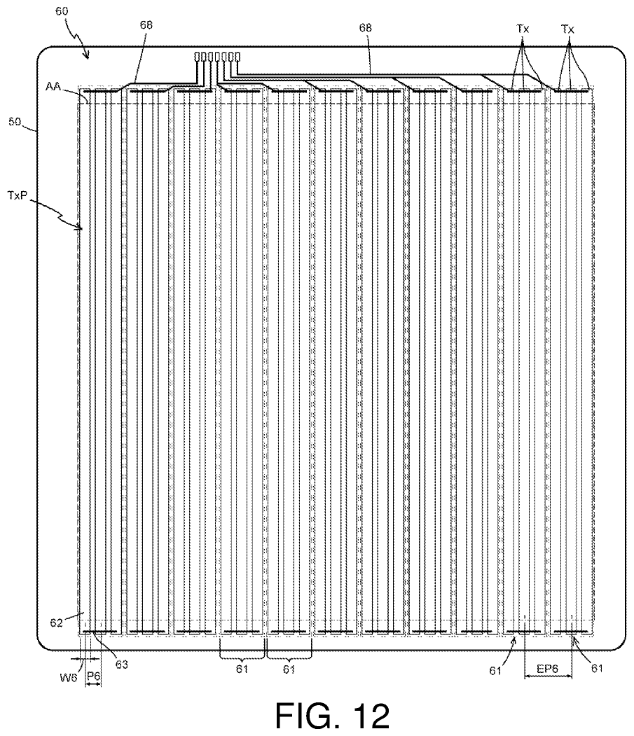

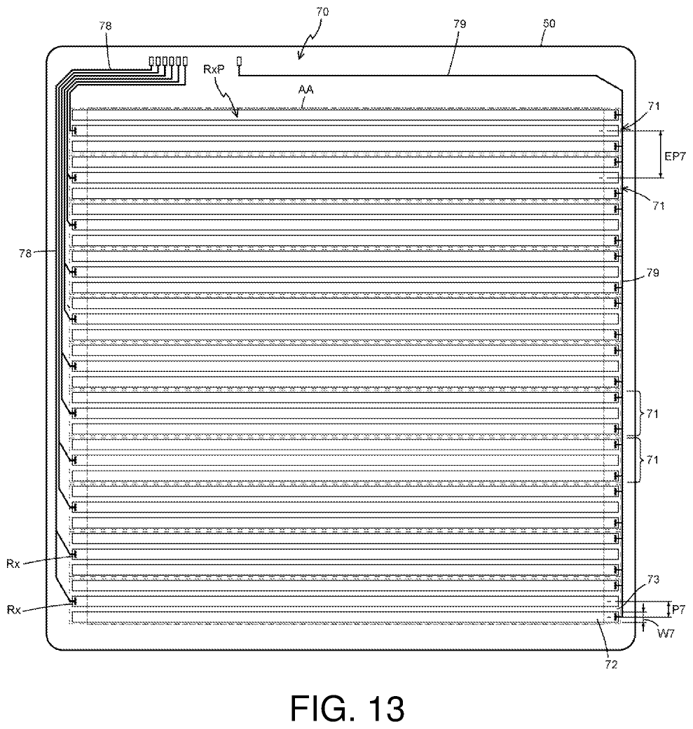

FIGS. 11-13 depict the second embodiment of the capacitive touch sensor using the abovementioned modularized touch glass board. In comparison with the first embodiment, this embodiment is a simplified structure of capacitive touch sensor. The primary difference therebetween is the upper touch sensing layer 70 of this embodiment do not have a grounding structure of the conductive bars. As shown in FIG. 12, the driving electrode group 61 of the upper touch sensing layer 60 includes three Y-axis conductive bars 62 along the Y-axis direction. The three Y-axis conductive bars 62 are electrically connected to form an active driving electrode unit Tx. The active driving electrode units Tx are connected to the driving signal wires 68. As shown in FIG. 13, the sensing electrode group 71 of the lower touch sensing layer 70 includes three X-axis conductive bars 72 along the X-axis direction. One of the three X-axis conductive bars 72 is set to be an active sensing electrode unit Rx. The active driving electrode units Tx are connected to the driving signal wires 68. The active sensing electrode units Rx are connected to the sensing signal wire 78 and the two of the X-axis conductive bars 72 which are not connected to the active sensing electrode units Rx are connected to the ground wire 79. The active driving electrode unit Tx is greater than the active sensing electrode unit Rx in area. The upper touch sensing layer 60 and the lower touch sensing layer 70 jointly constitute a capacitive touch sensor. Accordingly, changing the compositive number of the conductive bars in the driving electrode group 61 and the sensing electrode 71 and/or changing the number of the conductive bars connected to the active driving electrode unit Tx and the active sensing electrode unit Rx can easily adjust both performance of capacitance sensing and specification of the touch sensor.

In addition, according to the above embodiment of the modularized touch glass board, in the first and second embodiments of the capacitive touch sensor, the conductive bar may also be of a jagged strip shape or a strip shape formed by a series of geometric areas (such as rhombus). The low-resistance unit attached on the conductive bar can reduce the surface resistance of the ITO conductive bar.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A modularized touch glass board comprising a glass substrate with a first conductive layer and a second conductive layer, which are separately disposed on two opposite sides of the glass substrate, wherein the first conductive layer has a first preset trace pattern, the first preset trace pattern comprises first conductive bars which are arranged along a first direction and have the same widths, the first conductive bars are equally spaced out with a width of a first pitch, every adjacent two of the first conductive bars are separated by a first insulation gap; the second conductive layer has a second preset trace pattern, the second preset trace pattern comprises second conductive bars which are arranged along a second direction and have the same widths, the second conductive bars are equally spaced out with a width of a second pitch, every adjacent two of the second conductive bars are separated by a second insulation gap; the first direction is orthogonal to the second direction, the width of the first pitch is the same as the width of the second pitch, the width is below 2 mm, and each of the first insulation gap and the second insulation gap is between 20 and 500 μm.

2. The modularized touch glass board of claim 1, wherein each of the first and second conductive layers is a transparent conductive film and is made of metal oxide or graphene.

3. The modularized touch glass board of claim 2, wherein the metal oxide is indium tin oxide, indium zinc oxide, zinc aluminum oxide, tin antimony oxide or polyethylene dioxythiophene.

4. The modularized touch glass board of claim 1, wherein each of the first and second conductive bars is of a strip shape, a jagged strip shape or a strip shape formed by a series of geometric areas.

5. The modularized touch glass board of claim 1, further comprising a low-resistance unit electrically attached on each of the first and second conductive bars.

6. The modularized touch glass board of claim 5, wherein the low-resistance unit is made of gold, silver, copper, aluminum, molybdenum or an alloy thereof.

7. The modularized touch glass board of claim 5, wherein the low-resistance unit is composed of one or more of pointy, linear and planar shapes.

8. The modularized touch glass board of claim 5, wherein the low-resistance unit is a metal wire or a metal mesh.

9. The modularized touch glass board of claim 8, wherein a width of the metal wire is below 10 μm.

10. The modularized touch glass board of claim 9, wherein the low-resistance unit comprises one or more continuous straight linear metal wires or curved metal wires.

11. The modularized touch glass board of claim 8, wherein a shading rate of the metal mesh is under 1%.

12. A capacitive touch sensor comprising:
a substrate, being dielectric, and an active touch area being defined in a central portion thereof;
a first touch sensing layer, disposed on a first side of the substrate, having a first touch trace pattern and a first signal wire, the first touch trace pattern being formed in the active touch area of the substrate, the first signal wire being disposed outside the active touch area, the first touch trace pattern having first conductive bars which are arranged along a first direction, the first conductive bars being equally spaced out with a width of a first pitch, every adjacent two of the first conductive bars being separated by a first insulation gap, the first conductive bars being divided into multiple first electrode groups, the first electrode groups being spaced out with a width of a first electrode group pitch, each first electrode group comprising at least two of the first conductive bars, a first active electrode unit being formed by either one of the first conductive bars or selective more than one of the first conductive bars connected, and the first active electrode unit being electrically connected to the first signal wire; and
a second touch sensing layer, disposed on a second side of the substrate, having a second touch trace pattern and a second signal wire, the second touch trace pattern being formed in the active touch area of the substrate, the second signal wire being disposed outside the active touch area, the second touch trace pattern having second conductive bars which are arranged along a second direction, the second conductive bars being equally spaced out with a width of a second pitch, every adjacent two of the second conductive bars being separated by a second insulation gap, the second conductive bars being divided into multiple second electrode groups, the second electrode groups being spaced out with a width of a second electrode group pitch, each second electrode group comprising at least two of the second conductive bars, a second active electrode unit being formed by either one of the second conductive bars or selective more than one of the second conductive bars connected, and the second active electrode unit being electrically connected to the second signal wire;
wherein the first direction is orthogonal to the second direction, the width of the first electrode group pitch is the same as the width of the second electrode group pitch.

13. The capacitive touch sensor of claim 12, wherein the first pitch is the same as the second pitch in width, the width is below 2 mm, and each of the first insulation gap and the second insulation gap is between 500 and 20 μm.

14. The capacitive touch sensor of claim 12, wherein each of the first and second touch sensing layers is a transparent conductive film and is made of metal oxide or graphene.

15. The capacitive touch sensor of claim 14 wherein the metal oxide is indium tin oxide, indium zinc oxide, zinc aluminum oxide, tin antimony oxide or polyethylene dioxythiophene.

16. The capacitive touch sensor of claim 12 wherein each of the first and second conductive bars is of a strip shape, a jagged strip shape or a strip shape formed by a series of geometric areas.

17. The capacitive touch sensor of claim 12 wherein one or more of the first conductive bars of the first electrode group which is or are not connected to the first active electrode unit is or are connected to the ground wire.

18. The capacitive touch sensor of claim 12 wherein one or more of the second conductive bars of the second electrode group which is or are not connected to the second active electrode unit is or are connected to the ground wire.

19. The capacitive touch sensor of claim 12 wherein the first active electrode unit is a driving electrode, the second active electrode is a sensing electrode, and the first active electrode unit is greater than the second active electrode unit in area.

20. The capacitive touch sensor of claim 12 further comprising a low-resistance unit electrically attached on each of the first and second conductive bars, wherein the low-resistance unit is made of gold, silver, copper, aluminum, molybdenum or an alloy thereof.

21. The capacitive touch sensor of claim 20 wherein the low-resistance unit is composed of one or more of pointy, linear and planar shapes.

22. The capacitive touch sensor of claim 20 wherein the low-resistance unit is a metal wire or a metal mesh.
